(19) United States
(12) Patent Application Publication
(10) Pub. No.: US 2022/0181327 A1
(43) Pub. Date: Jun. 9, 2022

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventors: Xingsong SU, Hefei City (CN); Yanghao LIU, Hefei City (CN); Mengkang YU, Hefei City (CN); Weiping BAI, Hefei City (CN)

(21) Appl. No.: 17/452,266

(22) Filed: Oct. 26, 2021

Related U.S. Application Data
(63) Continuation of application No. PCT/CN2021/110734, filed on Aug. 5, 2021.

(30) Foreign Application Priority Data
Dec. 7, 2020 (CN) 202011431331.2

(51) Int. Cl. H01L 27/108; H01L 49/02; H01G 4/06; H01G 4/35

(52) U.S. Cl. CPC H01L 27/10829; H01L 28/60; H01L 27/10861; H01G 4/35; H01G 4/06

(57) ABSTRACT

A semiconductor structure and a manufacturing method thereof are disclosed in embodiments of the present disclosure. The semiconductor structure includes: a substrate; a plurality of discrete bottom electrodes located on the substrate; and a first dielectric layer and a second dielectric layer; where the first dielectric layer and the second dielectric layer are located between the bottom electrodes; the second dielectric layer is located between the first dielectric layer and each of the bottom electrodes; and a thickness of an upper portion of the second dielectric layer is less than a thickness of the bottom of the second dielectric layer.

### CROSS-REFERENCE TO RELATED APPLICATIONS

This is a continuation of International Patent Application No. PCT/CN2021/110734, filed on Aug. 5, 2021, which claims the priority to Chinese Patent Application No. 202011431331.2, titled “SEMICONDUCTOR STRUCTURE AND MANUFACTURING METHOD THEREOF” and filed on Dec. 7, 2020. The entire contents of International Patent Application No. PCT/CN2021/110734 and Chinese Patent Application No. 202011431331.2 are incorporated herein by reference.

### TECHNICAL FIELD

The present disclosure relates to, but is not limited to, a semiconductor structure and a manufacturing method thereof.

### BACKGROUND

As the thickness of the dynamic random access memory (DRAM) decreases continuously, the distance between bottom electrodes of capacitors becomes shorter, resulting in a severe leakage current of the capacitors in the DRAM, which affects device performance.

### SUMMARY

An overview of the subject matter detailed in the present disclosure is provided below, which is not intended to limit the protection scope of the claims.

Embodiments of the present disclosure provide a semiconductor structure and a manufacturing method thereof.

According to some embodiments, a first aspect of the present disclosure provides a semiconductor structure, including:

a substrate;

a plurality of discrete bottom electrodes located on the substrate; and

a first dielectric layer and a second dielectric layer, wherein the first dielectric layer and the second dielectric layer are located between the bottom electrodes;

where the second dielectric layer is located between the first dielectric layer and each of the bottom electrodes, and a thickness of an upper portion of the second dielectric layer is less than a thickness of the bottom of the second dielectric layer.

According to some embodiments, a second aspect of the present disclosure provides a method of manufacturing semiconductor structure, including:

providing a substrate;

forming a laminated structure on the substrate, the laminated structure including a first dielectric layer;

forming a plurality of capacitor holes in the laminated structure, each of the capacitor holes penetrating the first dielectric layer and exposing the substrate;

forming an initial dielectric layer at a bottom of each of the capacitor holes; and

removing part of the initial dielectric layer to form a second dielectric layer, the second dielectric layer exposing the substrate;

where a removal part at an upper portion of the initial dielectric layer is larger than a removal part at a lower portion of the initial dielectric layer.

Other aspects of the present disclosure are understandable upon reading and understanding of the drawings and detailed description.

### BRIEF DESCRIPTION OF THE DRAWINGS

The drawings incorporated into the specification and constituting part of the specification illustrate the embodiments of the present disclosure, and are used together with the description to explain the principles of the embodiments of the present disclosure. In these drawings, similar reference numerals are used to represent similar elements. The drawings in the following description are part rather than all of the embodiments of the present disclosure. Those skilled in the art may derive other drawings based on these drawings without creative efforts.

The preferred embodiments of the present disclosure are described in detail below with reference to the accompanying drawings to make the objectives, features and advantages of the present disclosure more obvious. The drawings are merely exemplary illustrations of the present disclosure, and are not necessarily drawn to scale. The same reference numerals in the drawings always represent the same parts.

FIG. 1 is a schematic structural diagram of a semiconductor structure according to an exemplary implementation;

FIG. 2 is a schematic flowchart of a method of manufacturing semiconductor structure according to an exemplary implementation;

FIG. 3 is a structural diagram of forming capacitor holes in a method of manufacturing semiconductor structure according to an exemplary implementation;

FIG. 4 is a structural diagram of forming an initial dielectric layer in a method of manufacturing semiconductor structure according to an exemplary implementation;

FIG. 5 is a structural diagram of forming a second dielectric layer in a method of manufacturing semiconductor structure according to an exemplary implementation;

FIG. 6 is a structural diagram of forming an initial dielectric layer in a method of manufacturing semiconductor structure according to another exemplary implementation;

FIG. 7 is a structural diagram of forming a second dielectric layer in a method of manufacturing semiconductor structure according to another exemplary implementation;

FIG. 8 is a structural diagram of forming bottom electrodes in a method of manufacturing semiconductor structure according to an exemplary implementation;

FIG. 9 is a structural diagram of removing a first sacrificial layer and a second sacrificial layer in a method of manufacturing semiconductor structure according to an exemplary implementation; and

FIG. 10 is a structural diagram of forming a dielectric layer in a method of manufacturing semiconductor structure according to an exemplary implementation.

### DETAILED DESCRIPTION

The technical solutions in the embodiments of the present disclosure are described below clearly and completely with reference to the drawings in the embodiments of the present disclosure. Apparently, the described embodiments are merely part rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

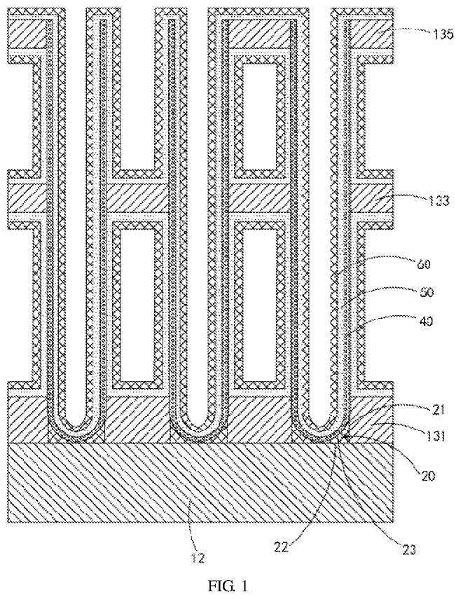

An embodiment of the present disclosure provides a semiconductor structure. Referring to FIG. 1, the semiconductor structure includes: a substrate 12; a plurality of discrete bottom electrodes 40 on the substrate 12; a first dielectric layer 131 and a second dielectric layer 20; wherein the first dielectric layer and the second dielectric layer are located between the bottom electrodes 40; the second dielectric layer 20 is located between the first dielectric layer 131 and each of the bottom electrodes 40; and a thickness of an upper portion of the second dielectric layer 20 is less than a thickness of the bottom of the second dielectric layer 20.

The semiconductor structure in an embodiment of the present disclosure includes a substrate 12, a plurality of bottom electrodes 40, a first dielectric layer 131, and a second dielectric layer 20. The thickness of the upper portion of the second dielectric layer 20 is made to be less than the thickness of the bottom of the second dielectric layer 20, that is, the bottom of the second dielectric layer 20 is thicker than the upper portion of the second dielectric layer 20, to avoid the problem of leakage current at the bottom of the bottom electrode 40, thereby improving the performance of the semiconductor structure.

To make the thickness of the upper portion of the second dielectric layer 20 less than the thickness of the bottom of the second dielectric layer 20, in a manufacturing process of the semiconductor structure, an initial dielectric layer 30 is formed at the bottom of each of capacitor holes, a part of the initial dielectric layer 30 is removed such that the remaining initial dielectric layer 30 is used as the second dielectric layer 20. A removal part at an upper portion of the initial dielectric layer 30 is larger than a removal part at the bottom of the initial dielectric layer 30, such that the thickness of the upper portion of the second dielectric layer 20 is less than the thickness of the bottom of the second dielectric layer 20. The thickness herein can be understood as the dimension of the second dielectric layer 20 in the direction along a surface of the substrate 12.

In some embodiments, a sidewall of the first dielectric layer 131 is perpendicular to a surface of the substrate 12, i.e., the sidewall of the first dielectric layer 131 forms a right angle with the surface of the substrate 12, and the second dielectric layer 20 fills the right angle, to avoid the charge accumulation of the bottom electrode at the right angle, thereby avoiding the leakage current of the bottom electrode at the corner.

In some embodiments, surfaces of the second dielectric layer 20 includes a side surface 21, a bottom surface 22, and a slope surface 23. The side surface 21 is directly contact with the first dielectric layer 131, the bottom surface 22 is directly contact with the substrate 12, and the slope surface 23 is directly contact with the bottom electrode 40.

For example, as can be seen in FIG. 1, the second dielectric layer 20 is set around the sidewall of the first dielectric layer 131 and wraps around the bottom of the bottom electrode 40, but it is necessary to ensure that the bottom electrode 40 is directly contact with the substrate 12. Since the second dielectric layer 20 fills the corner between the first dielectric layer 131 and the substrate 12, the accumulation of charges at the bottom of the bottom electrode 40 can be avoided.

In some embodiments, the slope surface 23 is an arc surface, and the arc surface is bent towards the inside of the second dielectric layer 20, i.e., there are no sharp corners on the slope surface 23, which can make the bottom of the bottom electrode 40 round, thus making it difficult to accumulate charges. In this way, the charges are uniformly distributed in the bottom electrode 40, thus reducing the leakage current.

In some embodiments, the second dielectric layer 20 is in the shape of a bowl with an opening at the bottom. For example, the bottom electrode 40 is cup-shaped, and the cross section thereof has a U-shaped bottom. The second dielectric layer 20 wraps around the bottom of the bottom electrode 40, and an opening is formed in the middle of the bottom surface 22. The opening ensures direct contact between the bottom of the bottom electrode 40 and the substrate 12. When there is a contact pad in the substrate 12, the bottom of the bottom electrode 40 can be electrically connected to the contact pad through the opening. The slope surface 23 is bent towards the inside of the second dielectric layer 20 to ensure that the thickness of the upper portion of the second dielectric layer 20 is less than the thickness of the bottom of the second dielectric layer 20.

In some embodiments, a material of the second dielectric layer 20 includes at least one of the following: SiCN, SiBN, SiSbN, and SiPN.

For example, the second dielectric layer 20 can be made of SiN doped with at least one of the following types of ions: C, B, P, and Sb.

In some embodiments, the height of the second dielectric layer 20 is not greater than the height of the first dielectric layer 131.

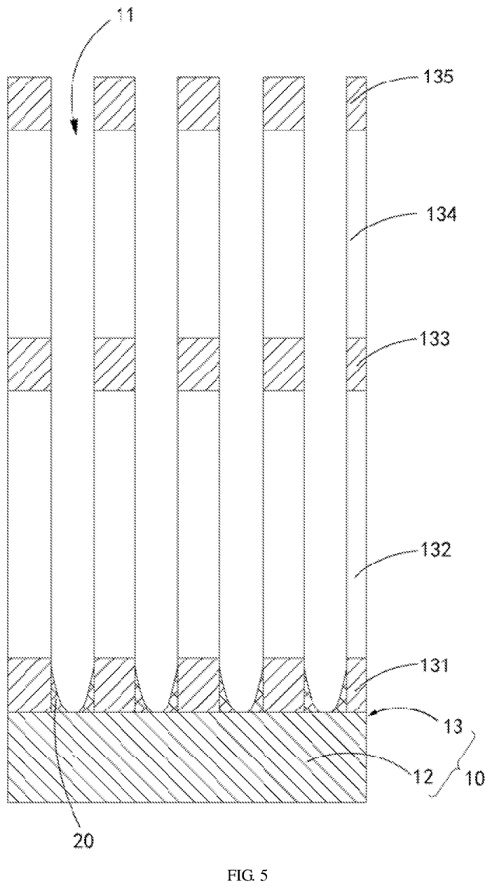

For example, with reference to FIG. 5, in the manufacturing process of the semiconductor structure, a first sacrificial layer 132 is formed on the first dielectric layer 131, and the first sacrificial layer 132 needs to be removed after the bottom electrode 40 is formed. Therefore, when the first sacrificial layer 132 and the second dielectric layer 20 are doped with the same type of ions, in order to ensure that the subsequent removal of the first sacrificial layer 132 does not affect the second dielectric layer 20, the second dielectric layer 20 can be located below the first sacrificial layer 132. In other words, the second dielectric layer 20 is located in a closed space defined by the bottom of the bottom electrode 40, the first dielectric layer 131 and the substrate 12, to prevent the second dielectric layer 20 from being affected during the subsequent removal of the first sacrificial layer 132 by a wet process.

In some embodiments, the height of the second dielectric layer 20 is greater than the height of the first dielectric layer 131.

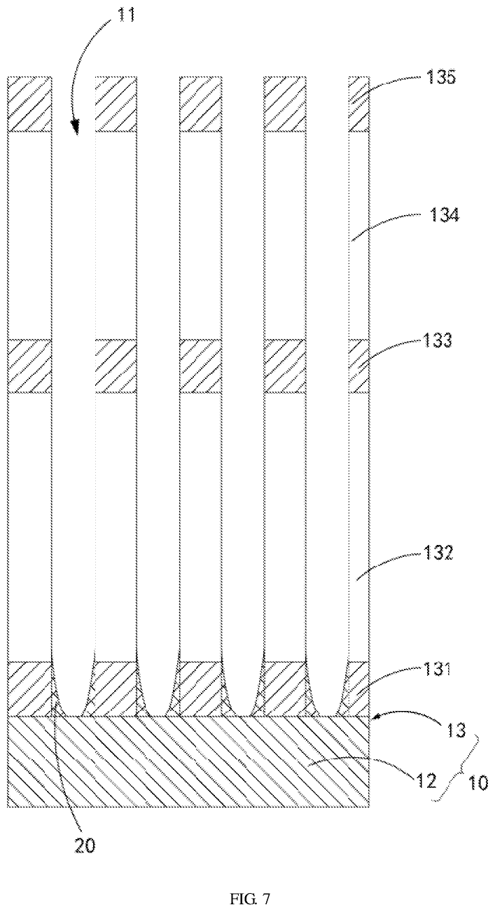

For example, with reference to FIG. 7, in the manufacturing process of the semiconductor structure, a first sacrificial layer 132 is formed on the first dielectric layer 131, and the first sacrificial layer 132 needs to be removed after the bottom electrode 40 is formed. Therefore, when the first sacrificial layer 132 and the second dielectric layer 20 are doped with different types of ions, the subsequent removal of the first sacrificial layer 132 does not affect the second dielectric layer 20, and it is unnecessary to consider whether the top of the second dielectric layer 20 exceeds that of the first dielectric layer 131. As shown in FIG. 7, the height of the second dielectric layer 20 is greater than the height of the first dielectric layer 131. By increasing the height of the second dielectric layer 20, the thickness of the bottom of the second dielectric layer 20 is increased, thus further reducing the leakage current.

When the first sacrificial layer 132 and the second dielectric layer 20 are doped with different types of ions, it is still possible that the height of the second dielectric layer 20 is not greater than the height of the first dielectric layer 131. For example, an etching selection ratio between the first sacrificial layer 132 and the second dielectric layer 20 can be adjusted by selecting a suitable etching material, so as to remove the first sacrificial layer 132 and retain the second dielectric layer 20.

In some embodiments, the substrate 12 includes a plurality of discrete contact pads. The bottom electrodes 40 are directly contact with the contact pads, thus ensuring the electrical connection between the bottom electrodes 40 and the contact pads.

For example, a material of the contact pads includes, but is not limited to, tungsten (W). The plurality of bottom electrodes 40 are provided corresponding to the plurality of contact pads in a one-to-one manner.

In some embodiments, the semiconductor structure further includes: a first support layer 133, located in a middle portion of each of the bottom electrodes 40 and separating the bottom electrodes 40 from each other; a second support layer 135, located at an upper portion of each of the bottom electrodes 40 and separating the bottom electrodes 40 from each other; a dielectric layer 50, covering a surface of each of the bottom electrodes 40; and a top electrode 60, covering a surface of the dielectric layer 50.

For example, as shown in FIG. 1, the first dielectric layer 131, the first support layer 133, and the second support layer 135 are sequentially provided along a height direction. The first dielectric layer 131 is spaced apart from the first support layer 133, and the first support layer 133 is spaced apart from the second support layer 135. The first dielectric layer 131, the first support layer 133, and the second support layer 135 achieve the effect of supporting the bottom electrode 40 and the top electrode 60.

In some embodiments, the first dielectric layer 131, the first support layer 133, and the second support layer 135 may be made of the same material; alternatively, the first dielectric layer 131, the first support layer 133, and the second support layer 135 may be made of different materials. For example, the first dielectric layer 131, the first support layer 133, and the second support layer 135 may all include silicon nitride (SiN).

In some embodiments, the dielectric layer 50 is provided between the bottom electrode 40 and the top electrode 60. The material of the dielectric layer 50 includes a high-k material, which includes, but is not limited to, alumina, zirconia, hafnium oxide or other high-k materials, or any combination thereof.

In some embodiments, a material of the bottom electrodes 40 includes, but is not limited to, titanium nitride (TiN).

In some embodiments, a material of the top electrode 60 includes, but is not limited to, titanium nitride.

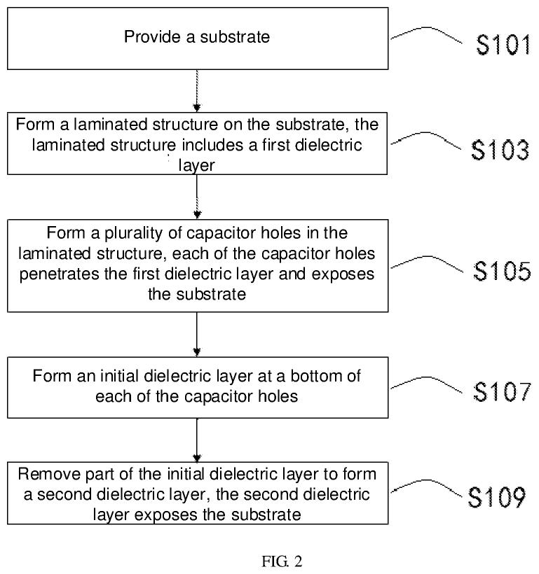

An embodiment of the present disclosure further provides a method of manufacturing semiconductor structure. As shown in FIG. 2, the method of manufacturing semiconductor structure includes the following steps:

S101: Provide a substrate 12.

S103: Form a laminated structure 13 on the substrate 12, the laminated structure 13 including a first dielectric layer 131.

S105: Form a plurality of capacitor holes 11 in the laminated structure 13, each of the capacitor holes 11 penetrating the first dielectric layer 131 and exposing the substrate 12.

S107: Form an initial dielectric layer 30 at the bottom of each of the capacitor holes 11.

S109: Remove part of the initial dielectric layer 30 to form a second dielectric layer 20, the second dielectric layer 20 exposing the substrate 12.

A removal part at an upper portion of the initial dielectric layer 30 is larger than a removal part at a lower portion of the initial dielectric layer 30.

In the method of manufacturing semiconductor structure in an embodiment of the present disclosure, the initial dielectric layer 30 is formed at the bottom of each of the capacitor holes 11, and the removal part at the upper portion of the initial dielectric layer 30 is made to be larger than the removal part at the lower portion of the initial dielectric layer 30, such that the thickness of the upper portion of the formed second dielectric layer 20 is less than the thickness of the bottom of the second dielectric layer 20, to avoid the problem of leakage current at the bottom of the bottom electrode 40, thereby improving the performance of the semiconductor structure.

In some embodiments, the substrate 12 and the laminated structure 13 form a capacitor body 10, the capacitor hole 11 is formed in the capacitor body 10, and the capacitor hole 11 penetrates the laminated structure 13 to expose the substrate 12.

In some embodiments, the laminated structure 13 includes a first sacrificial layer 132. The first sacrificial layer 132 is formed on the first dielectric layer 131, where the initial dielectric layer 30 and the first sacrificial layer 132 are doped with the same type of ions.

For example, the first dielectric layer 131 is formed on the surface of the substrate 12, and then the first sacrificial layer 132 is formed on the surface of the first dielectric layer 131. After the capacitor holes 11 are formed, the initial dielectric layer 30 is formed at the bottom of each of the capacitor holes 11. The initial dielectric layer 30 and the first sacrificial layer 132 may be doped with ions through ion injection.

The first dielectric layer 131 and the first sacrificial layer 132 may be formed by using a physical vapor deposition (PVD) process, a chemical vapor deposition (CVD) process, or an atomic layer deposition (ALD) process.

In some embodiments, the doping ions include at least one of the following types: C, B, P, and Sb. That is, at least one type of C, B, P, and Sb ions can be doped in the initial dielectric layer 30 and the first sacrificial layer 132 to make it easier for the initial dielectric layer 30 to form a smooth transition in the etching process.

In some embodiments, the height of the second dielectric layer 20 is not greater than the height of the first dielectric layer 131.

For example, when the first sacrificial layer 132 and the second dielectric layer 20 are doped with the same type of ions, in order to ensure that the subsequent removal of the first sacrificial layer 132 does not damage the second dielectric layer 20, the second dielectric layer 20 can be positioned below the first sacrificial layer 132, i.e., the height of the second dielectric layer 20 is not greater than the height of the first dielectric layer 131. After the second dielectric layer 20 is formed, the bottom electrode 40 is formed in each of the capacitor holes 11. For example, the bottom electrode made of titanium nitride is formed using a PVD or CVD process. The second dielectric layer 20 is completely located in a closed space defined by the bottom of the bottom electrode 40, the first dielectric layer 131 and the substrate 12, which prevents the second dielectric layer 20 from being affected when the first sacrificial layer 132 is subsequently removed by the wet process.

In some embodiments, the laminated structure 13 further includes a first support layer 133, a second sacrificial layer 134, and a second support layer 135 that are sequentially formed on the first sacrificial layer 132.

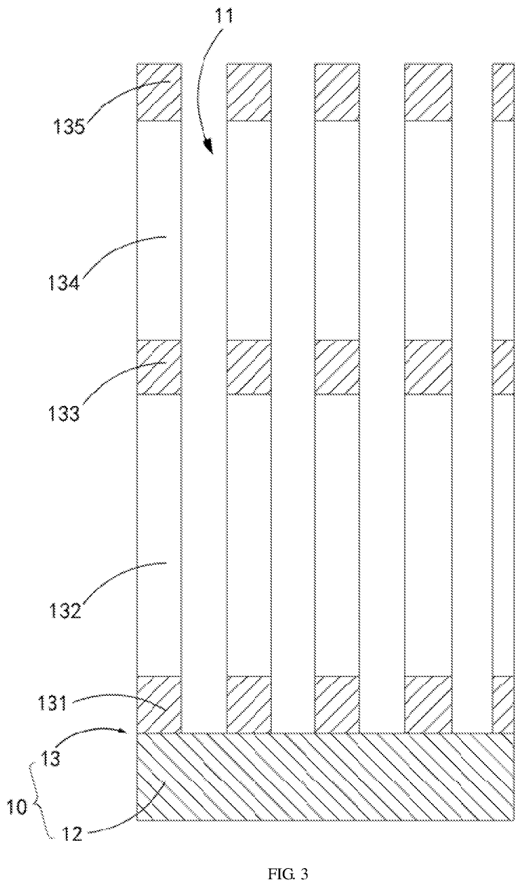

For example, the specific forming process of the second dielectric layer 20 is illustrated below with reference to FIG. 3 to FIG. 5.

A substrate 12 is provided, and a first dielectric layer 131, a first sacrificial layer 132, a first support layer 133, a second sacrificial layer 134, and a second support layer 135 are sequentially formed on the substrate 12. That is, the first dielectric layer 131, the first sacrificial layer 132, the first support layer 133, the second sacrificial layer 134, and the second support layer 135 are used as a laminated structure 13. The laminated structure 13 is etched to form a plurality of capacitor holes 11 and expose an upper surface of the substrate 12, as shown in FIG. 3.

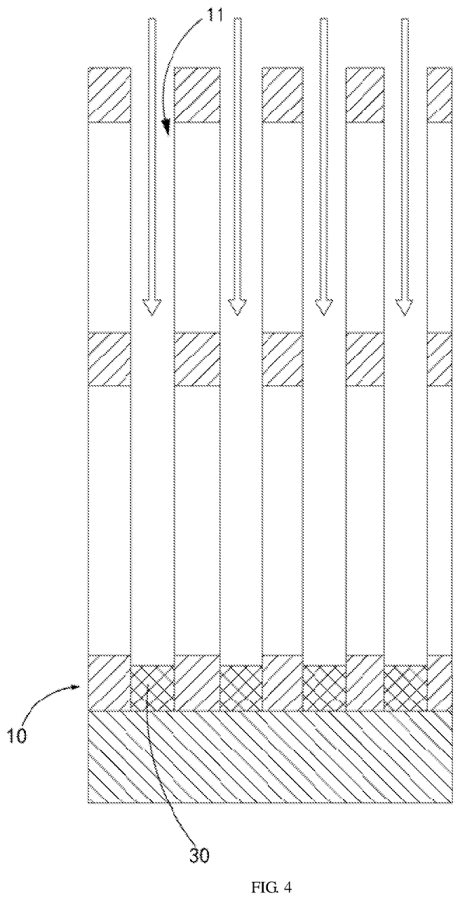

An initial dielectric layer 30 is filled at the bottom of each of the capacitor holes 11, and the top of the initial dielectric layer 30 does not exceed the bottom of the first sacrificial layer 132. As shown in FIG. 4, the top of the initial dielectric layer 30 is lower than the bottom of the first sacrificial layer 132.

The initial dielectric layer 30 is partially etched. A removal part at an upper portion of the initial dielectric layer 30 is larger than a removal part at a lower portion of the initial dielectric layer 30, and part of the substrate 12 is exposed, to form the second dielectric layer 20 as shown in FIG. 5.

In some embodiments, the laminated structure 13 includes a first sacrificial layer 132. The first sacrificial layer 132 is formed on the first dielectric layer 131, where the second dielectric layer 20 and the first sacrificial layer 132 are doped with different types of ions, and the height of the second dielectric layer 20 is greater than the height of the first dielectric layer 131.

For example, when the first sacrificial layer 132 and the second dielectric layer 20 are doped with different types of ions, the process of removing the first sacrificial layer 132 does not affect the second dielectric layer 20. Therefore, the top of the second dielectric layer 20 is higher than the bottom of the first sacrificial layer 132, to ensure the thickness of the bottom of the second dielectric layer 20, thus avoiding the problem of current leakage to the greatest extent.

In some embodiments, the laminated structure 13 further includes a first support layer 133, a second sacrificial layer 134, and a second support layer 135 that are sequentially formed on the first sacrificial layer 132.

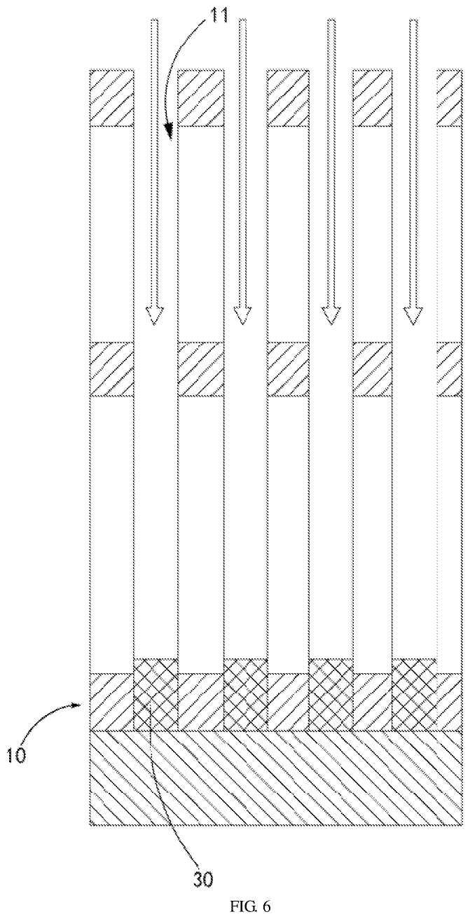

For example, the specific forming process of the second dielectric layer 20 is illustrated below with reference to FIG. 3, FIG. 6, and FIG. 7.

A substrate 12 is provided, and a first dielectric layer 131, a first sacrificial layer 132, a first support layer 133, a second sacrificial layer 134, and a second support layer 135 are sequentially formed on the substrate 12. That is, the first dielectric layer 131, the first sacrificial layer 132, the first support layer 133, the second sacrificial layer 134, and the second support layer 135 are used as a laminated structure 13. The laminated structure 13 is etched to form a plurality of capacitor holes 11 and expose an upper surface of the substrate 12, as shown in FIG. 3.

An initial dielectric layer 30 is filled at the bottom of each of the capacitor holes 11, and the top of the initial dielectric layer 30 is higher than the bottom of the first sacrificial layer 132, as shown in FIG. 6.

The initial dielectric layer 30 is partially etched. A removal part at an upper portion of the initial dielectric layer 30 is larger than a removal part at a lower portion of the initial dielectric layer 30, and part of the substrate 12 is exposed, to form the second dielectric layer 20 as shown in FIG. 7.

For the foregoing embodiment, it should be noted that the first support layer 133, the second sacrificial layer 134, the second support layer 135, and the initial dielectric layer 30 may be formed by using a PVD process, a CVD process, or an ALD process.

The first dielectric layer 131, the first support layer 133, and the second support layer 135 may be made of the same material; alternatively, the first dielectric layer 131, the first support layer 133, and the second support layer 135 may be made of different materials. In this embodiment, the first dielectric layer 131, the first support layer 133, and the second support layer 135 may include silicon nitride.

A material of the second dielectric layer 20 includes at least one of the following: SiCN, SiBN, SiSbN, and SiPN. For example, the initial dielectric layer 30 may be formed by doping silicon nitride with at least one of the following types of ions: C, B, P, and Sb.

In some embodiments, the method of manufacturing semiconductor structure further includes: forming a bottom electrode 40 in each of the capacitor holes 11, the bottom of the bottom electrode 40 being directly contact with the substrate 12; removing the first sacrificial layer 132 and the second sacrificial layer 134; forming a dielectric layer 50 on a surface of the bottom electrode 40; and forming a top electrode 60 on a surface of the dielectric layer 50.

For example, after the structure shown in FIG. 5 or FIG. 7 is formed, the bottom electrode 40 is formed in the capacitor hole 11, and the first sacrificial layer 132 and the second sacrificial layer 134 are removed. The first dielectric layer 131, the first support layer 133, and the second support layer 135 achieve an effect of supporting the bottom electrode 40. The dielectric layer 50 is formed on the surface of the bottom electrode 40. The dielectric layer 50 further covers the upper surface of the second support layer 135. The top electrode 60 is formed on the surface of the dielectric layer 50. For details, refer to the semiconductor structure shown in FIG. 1.

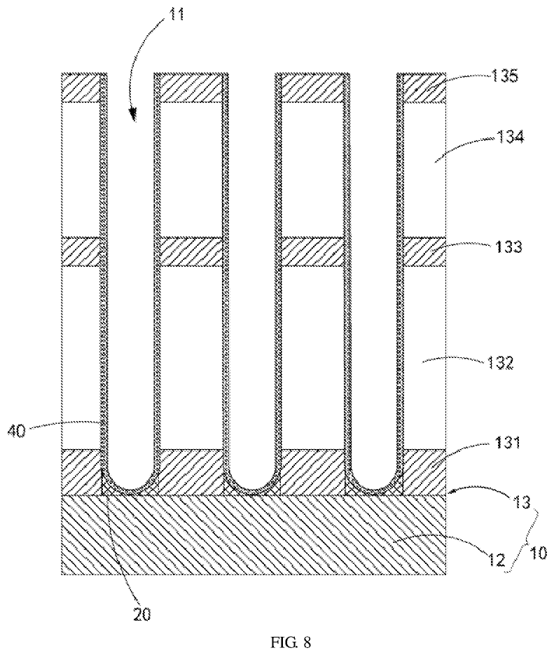

For example, in the structure shown in FIG. 5, the bottom electrode 40 is formed in the capacitor hole 11, as shown in FIG. 8. The first sacrificial layer 132 and the second sacrificial layer 134 in FIG. 8 are removed. In this case, the bottom electrode 40 can be supported by the first dielectric layer 131, the first support layer 133, and the second support layer 135.

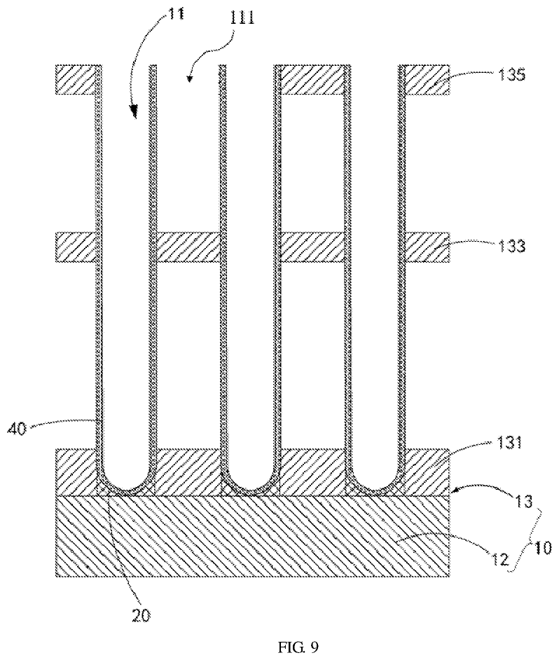

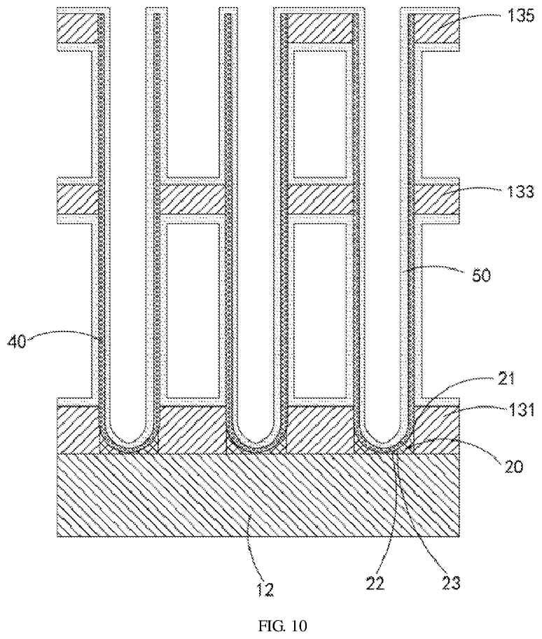

Specifically, as shown in FIG. 9, part of the second support layer 135 is removed to form a first opening 111, where the first opening 111 exposes the second sacrificial layer 134, and the second sacrificial layer 134 is removed by a wet etching process; then part of the first support layer 133 is exposed in the same manner to expose the first sacrificial layer 132, and the first sacrificial layer 132 is removed by a wet etching process. The dielectric layer 50 is covered on the surface of the bottom electrode 40, and the dielectric layer 50 covers the first support layer 133 and the second support layer 135, which is specifically as shown in FIG. 10. The top electrode 60 is covered on the surface of the dielectric layer 50, to form the semiconductor structure as shown in FIG. 1.

In some embodiments, the substrate 12 includes a plurality of discrete contact pads, and the bottom electrodes 40 are directly contact with the contact pads. A material of the contact pads includes, but is not limited to, tungsten (W).

The first sacrificial layer 132 and the second sacrificial layer 134 may be removed by using a wet etching process. A process for forming the bottom electrode 40, the dielectric layer 50, and the top electrode 60 may be a PVD process, a CVD process, or an ALD process in the related art, which is not limited therein.

A material of the bottom electrode 40 includes, but is not limited to, titanium nitride.

A material of the top electrode 60 includes, but is not limited to, titanium nitride.

A material of the dielectric layer 50 includes a high-k material, which includes, but is not limited to, at least one of the following: alumina, zirconia, and hafnium oxide.

Each embodiment or implementation in the specification of the present disclosure is described in a progressive manner. Each embodiment focuses on the difference from other embodiments, and the same and similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

A semiconductor structure and a manufacturing method thereof are disclosed in the embodiments of the present disclosure. The thickness of the upper portion of the second dielectric layer is made to be less than the thickness of the bottom of the second dielectric layer, that is, the bottom of the second dielectric layer is thicker than the upper portion of the second dielectric layer, to avoid the problem of leakage current at the bottom of the bottom electrode, thereby improving the performance of the semiconductor structure.

1. A semiconductor structure, comprising:
a substrate;
a plurality of discrete bottom electrodes located on the substrate; and
a first dielectric layer and a second dielectric layer, wherein the first dielectric layer and the second dielectric layer are located between the bottom electrodes;
wherein the second dielectric layer is located between the first dielectric layer and each of the bottom electrodes, and a thickness of an upper portion of the second dielectric layer is less than a thickness of a bottom of the second dielectric layer.

2. The semiconductor structure according to claim 1, wherein a sidewall of the first dielectric layer is perpendicular to a surface of the substrate.

3. The semiconductor structure according to claim 1, wherein surfaces of the second dielectric layer comprise a side surface, a bottom surface and a slope surface, the side surface is directly contact with the first dielectric layer, the bottom surface is directly contact with the substrate, and the slope surface is directly contact with the bottom electrode.

4. The semiconductor structure according to claim 3, wherein the slope surface is an arc surface, and the arc surface is bent towards an inside of the second dielectric layer.

5. The semiconductor structure according to claim 1, wherein a material of the second dielectric layer comprises at least one of SiCN, SiBN, SiSbN, and SiPN.

6. The semiconductor structure according to claim 3, wherein a height of the second dielectric layer is not greater than a height of the first dielectric layer.

7. The semiconductor structure according to claim 3, wherein a height of the second dielectric layer is greater than a height of the first dielectric layer.

8. The semiconductor structure according to claim 3, wherein the substrate comprises a plurality of discrete contact pads, and the bottom electrodes are directly contact with the contact pads.

9. The semiconductor structure according to claim 1, wherein the semiconductor structure further comprises:
a first support layer, located in a middle portion of each of the bottom electrodes, wherein the first support layer separates the bottom electrodes from each other;
a second support layer, located in an upper portion of each of the bottom electrodes, wherein the second support layer separates the bottom electrodes from each other;
a dielectric layer, covering a surface of each of the bottom electrodes; and
a top electrode, covering a surface of the dielectric layer.

10. The semiconductor structure according to claim 1, wherein the second dielectric layer is in the shape of a bowl with an opening at the bottom.

11. A method of manufacturing semiconductor structure, comprising:
providing a substrate;
forming a laminated structure on the substrate, the laminated structure comprising a first dielectric layer;
forming a plurality of capacitor holes in the laminated structure, each of the capacitor holes penetrating the first dielectric layer and exposing the substrate;
forming an initial dielectric layer at a bottom of each of the capacitor holes; and
removing part of the initial dielectric layer to form a second dielectric layer, the second dielectric layer exposing the substrate;
wherein a removal part at an upper portion of the initial dielectric layer is larger than a removal part at a lower portion of the initial dielectric layer.

12. The method of manufacturing semiconductor structure according to claim 11, wherein the laminated structure comprises a first sacrificial layer, the first sacrificial layer is formed on the first dielectric layer;
wherein the second dielectric layer and the first sacrificial layer are doped with the same type of ions.

13. The method of manufacturing semiconductor structure according to claim 12, wherein the ions comprise at least one of C, B, P, and Sb.

14. The method of manufacturing semiconductor structure according to claim 12, wherein
a height of the second dielectric layer is not greater than a height of the first dielectric layer.

15. The method of manufacturing semiconductor structure according to claim 11, wherein
the laminated structure comprises a first sacrificial layer, the first sacrificial layer is formed on the first dielectric layer;
wherein the second dielectric layer and the first sacrificial layer are doped with different types of ions, and a height of the second dielectric layer is greater than a height of the first dielectric layer.

16. The method of manufacturing semiconductor structure according to claim 12, wherein
the laminated structure further comprises a first support layer, a second sacrificial layer, and a second support layer; the first support layer, the second sacrificial layer, and the second support layer are sequentially formed on the first sacrificial layer.

17. The method of manufacturing semiconductor structure according to claim 16, further comprising:
forming a bottom electrode in each of the capacitor holes, a bottom of the bottom electrode being directly contact with the substrate;
removing the first sacrificial layer and the second sacrificial layer;
forming a dielectric layer on a surface of each of the bottom electrodes; and
forming a top electrode on a surface of the dielectric layer.
